(19) United States
(12) Patent Application Publication
(10) Pub. No.: US 2022/0374145 A1
(43) Pub. Date: Nov. 24, 2022

(54) ELECTRONIC DEVICE FOR OUTPUTTING KEYBOARD INTERFACE AND CONTROL METHOD THEREFOR

(71) Applicant: LG ELECTRONICS INC., Seoul (KR)

(72) Inventors: Hee Chul LEE, Seoul (KR); Jin Soo CHOI, Seoul (KR)

(73) Assignee: LG ELECTRONICS INC., Seoul (KR)

(21) Appl. No.: 17/755,599

(22) PCT Filed: Nov. 6, 2019
(86) PCT No.: PCT/KR2019/014982

§ 371 Date: May 3, 2022

(51) Int. Cl. G06F 3/04886; G06F 3/14; G06F 3/04817

(52) U.S. Cl. CPC G06F 3/04886; G06F 3/1423; G06F 3/04817

(57) ABSTRACT

Provided is an electronic device in which a first body having a first display and a second body having a second display are selectively coupled and linked, the electronic device including at least one processor which is provided at the first body so as to control the first display and which controls the first display and the second display on the basis of coupling to the second body, wherein the at least one processor is configured to identify whether the second body is coupled and on the basis of the coupling to the second body, output one area of a keyboard interface corresponding to a keyboard on the first display and output another area of the keyboard interface on the second display.

### TECHNICAL FIELD

This disclosure relates to an electronic device that outputs a keyboard interface corresponding to a keyboard through a plurality of displays and a method of controlling the same.

### BACKGROUND ART

With the development of electronic technology, electronic devices such as smartphones capable of providing users with various multimedia contents such as moving pictures and photos have been widely used.

Recently, the demand for such multimedia content is rapidly increasing, and in response to it, the user's need to watch multimedia content in a more comfortable environment is also increasing. Accordingly, development of an electronic device providing a screen having a larger area is being actively conducted.

As part of such development, mobile terminals emphasizing portability also tend to include a plurality of displays in order to provide a screen with a larger area.

Meanwhile, in the case of an electronic device emphasizing portability, such as a mobile terminal, a keyboard function is provided by outputting a keyboard interface corresponding to a keyboard on a display instead of separate keyboard hardware.

Since a general mobile terminal is similar in size to the size of a user's one hand, the user may input text through a keyboard interface by holding the mobile terminal with both hands or one had. However, when the mobile terminal includes a plurality of displays, when a keyboard interface is displayed on any one display, it may cause inconvenience in text input.

For example, in the case of an electronic device including a plurality of displays arranged side by side on the left and right sides, the keyboard interface may be displayed only on the right display. In this case, since both hands must hold the right display in order to input text using both hands, the left display may need to be unstable in the air. Further, due to the left display, a range in which the user's left hand may be positioned may be limited, which may cause inconvenience.

### DISCLOSURE OF INVENTION

### Technical Goals

An aspect provides an electronic device that enables easier and efficient text inputs by outputting a keyboard interface using a plurality of displays, and a method controlling the same.

The problems to be solved by example embodiments of the present disclosure are not limited to those mentioned above. Although not mentioned, it may include a purpose that may be clearly understood by those of ordinary skill in the art to which the present disclosure pertains from the description below.

### Technical Solutions

According to an aspect, there is provided an electronic device in which a first body having a first display and a second body having a second display are selectively coupled and linked, the electronic device includes at least one processor which is provided at the first body so as to control the first display and which controls the first display and the second display on the basis of coupling to the second body, wherein the at least one processor is configured to identify whether the second body is coupled and on the basis of the coupling to the second body, output one area of a keyboard interface corresponding to a keyboard on the first display and output another area of the keyboard interface on the second display.

According to another aspect, there is also provided a method of controlling an electronic device in which a first body having a first display and a second body having a second display are selectively coupled and linked, the method including identifying whether the second body is coupled and based on coupling to the second body, outputting an area of a keyboard interface corresponding to a keyboard on the first display and outputting another area of the keyboard interface on the second display.

According to another aspect, there is also provided a computer-readable recording medium configured to store instructions for executing identifying whether a second body is coupled for an electronic device in which a first body including a first display and the second body including a second display are selectively coupled, and based on coupling to the second body, outputting an area of a keyboard interface corresponding to a keyboard to the first display and outputting another area of the keyboard interface to the second display.

### Effects

According to example embodiments, by outputting the keyboard interface using a plurality of displays, text inputs may be performed more easily and efficiently.

Effects that may be obtained in the example embodiments of the present disclosure are not limited to the effects mentioned above. Other effects not mentioned will be clearly understood by those of ordinary skill in the art to which the present disclosure belongs from the following description.

### BRIEF DESCRIPTION OF DRAWINGS

FIG. 1 is a block diagram illustrating a mobile terminal related to the present disclosure.

FIG. 2 is a view illustrating a state before a mobile terminal is coupled to an auxiliary device in a terminal set related to the present disclosure.

FIG. 3 is a diagram illustrating a state in which a mobile terminal is coupled to an auxiliary device.

FIG. 4 illustrates a state in which a folio cover of the auxiliary device is detached from the state of FIG. 3.

FIG. 5 illustrates a front perspective view and a rear perspective view of a mobile terminal related to the present disclosure.

FIG. 6 is a conceptual diagram of an electronic device according to an example embodiment of the present disclosure.

FIG. 7 is a functional block diagram of an electronic device according to an example embodiment of the present disclosure.

FIG. 8 is a flowchart illustrating a flow of each step of a method for controlling an electronic device according to an example embodiment of the present disclosure.

FIG. 9 is a diagram illustrating an example embodiment in which an electronic device outputs a keyboard interface and an application icon according to an example embodiment of the present disclosure.

FIG. 10 illustrates an example of an input related to a keyboard interface in an electronic device according to an example embodiment of the present disclosure.

FIG. 11 is a diagram illustrating another example of an input related to a keyboard interface in an electronic device according to an example embodiment of the present disclosure.

FIG. 12 is a diagram illustrating an example of outputting a keyboard interface based on a posture of an electronic device according to an example embodiment of the present disclosure.

FIG. 13 is a diagram illustrating an example of a text type of a keyboard interface of an electronic device according to an example embodiment of the present disclosure.

### BEST MODE FOR CARRYING OUT THE INVENTION

Advantages and features of the example embodiments of the present disclosure, and methods for achieving them, will become apparent with reference to the example embodiments described below in detail in conjunction with the accompanying drawings. However, the present disclosure is not limited to the example embodiments disclosed below, and may be implemented in various forms. The example embodiments in the present disclosure are provided so that the disclosure of the present specification is complete, and to fully inform the scope of the present specification to those of ordinary skill in the art to which the present disclosure belongs. The scope of the present disclosure is only defined by the claims.

In describing the example embodiments of the present disclosure, detailed descriptions of will-known functions or configurations will be omitted unless it is actually necessary to describe the example embodiments of the present disclosure. In addition, the terms to be described later are terms defined in consideration of functions in the example embodiments of the present disclosure, which may vary according to intentions or customs of users and operators. Therefore, the definitions should be made based on the content throughout the present disclosure.

Since the present disclosure may make various changes and include various example embodiments, specific example embodiments are illustrated in the drawings and described in the detailed description. However, it is not intended to limit the present disclosure to the specific example embodiments, and the present disclosure should be understood as including all modification, equivalents, and substitutes included in the spirit and the scope of the present disclosure.

Terms including an ordinal number such as 1st, 2^{nd}, etc. may be used to describe various components, but the components are not limited by the terms. The terms are used only for distinguishing one component from another.

When an element is inferred to as “being connected to” or “access” another element, it is understood that it may be directly connected to or access the other element, but another element may exist in between. In the present disclosure, terms such as “comprise” or “have” are intended to designate that a feature, number, step, action, component, part or combination thereof described in the present disclosure is present. It should be understood that the terms do not preclude the possibility of addition or existence of one or more other features or numbers, steps, operations, components, parts, or combinations thereof.

Electronic devices described herein include mobile phones, smart phones, laptop computers, digital broadcasting terminals, personal digital assistants (PDAs), portable multimedia players (PMPs), navigation, slate PCs, tablet PCs, ultrabooks, wearable devices (e.g., a watch-type terminal (smartwatch), a glasses-type terminal (smart glasses), and a head mounted display (HMD)).

However, those skilled in the art will readily appreciate that configurations according to the example embodiments described in the present disclosure may also be applied to a fixed terminal such as a digital TV, a desktop computer and a digital signage.

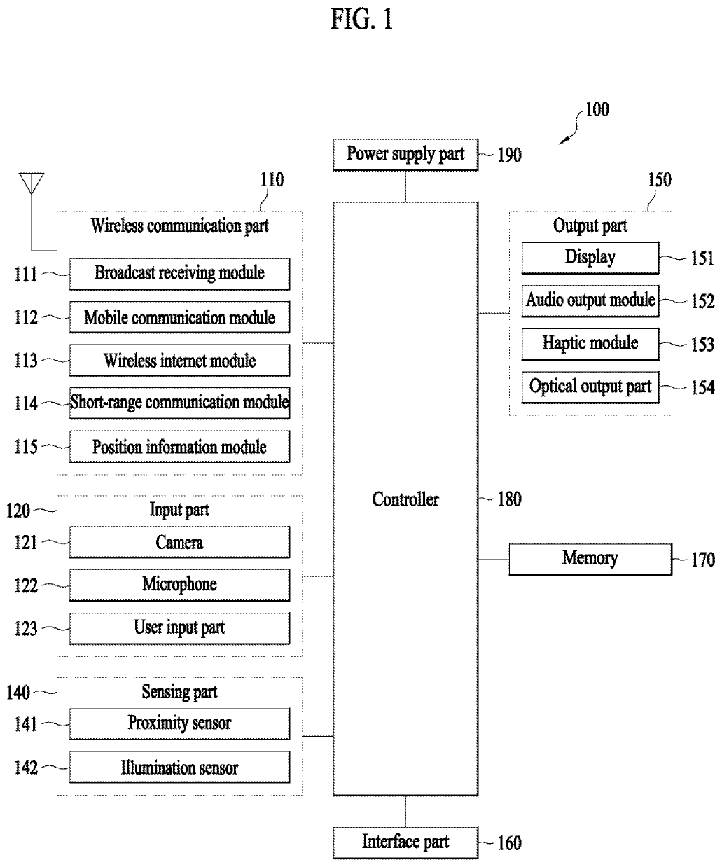

FIG. 1 is a block diagram illustrating an electronic device 100 related to an example embodiment of the present disclosure.

An electronic device 100 may include a wireless communication part 110, an input part 120, a sensing part 140, an outer part 150, an interface 160, a memory 170, a controller 180, and a power supply 190. The components illustrated in FIG. 1 are not essential to implementing a mobile terminal, so the mobile terminal described herein may have more or fewer components than those listed above. Meanwhile, the electronic device 100 may be implemented as a mobile terminal according to an example embodiment.

Specifically, the wireless communication part 110 may include at least one module that enables wireless communication to be performed between the electronic device 100 and a wireless communication system, between the electronic device 100 and another electronic device, or between the electronic device 100 and an external server. The wireless communication part 110 may include one or more modules that connect the electronic device 100 to one or more networks.

The wireless communication part 110 may include at least one of a broadcast receiver 111, a mobile communication part 112, a wireless Internet part 113, a short-range communication part 114, and a position information part 115.

The input part 120 may include a camera 121 or an image input part to receive an image signal input, a microphone 122 or an audio input part to receive an audio signal input, or a user input part 123, for example, a touch key and a mechanical key to receive information from a user. Voice data or image data collected by the input part 120 may be analyzed and processed as a control command of the user.

The sensing part 140 may include one or more sensors to sense at least one of information in the mobile terminal, surrounding environment information of the mobile terminal, or user information. For example, the sensing part 140 may include at least one of a proximity sensor 141, an illumination sensor 142, a touch sensor, an acceleration sensor, a magnetic sensor, a gravity (G)-sensor, a gyroscope sensor, a motion sensor, an RGB sensor, an infrared (IR) sensor, an ultrasonic sensor, a finger scan sensor, an optical sensor, for example, a camera (refer to the camera 121), a microphone (refer to the microphone 122), a battery gauge, an environment sensor (for example, a barometer, a hygrometer, a thermometer, a radioactivity sensor, a heat sensor, and a gas detection sensor), and a chemical sensor (for example, an electronic nose, a healthcare sensor, and a biometric sensor). In the present disclosure, the mobile terminal may use a combination of pieces of information sensed in at least two sensors among the aforementioned sensors.

The output part 150 may be to generate a visual, auditory, or tactile output. The output part 150 may include at least one of the display 151, an acoustic output part 152, a haptic part 153, and an optical output part 154. The display 151 of the electronic device 100 corresponds to a first display described in FIG. 1 to FIG. 3. The display 151 may form a layer structure or an integrated structure with a touch sensor to implement a touch screen. The touch screen may function as the user input part 123 that provides an input interface between the electronic device 100 and a user and simultaneously, provide an output interface between the electronic device 100 and the user.

The interface 160 may function as a passage to various types of external devices connected to the electronic device 100. For example, the interface 160 may include at least one of a wired/wireless headset port, an external charger port, a wired/wireless data port, a memory card port, a port connecting a device equipped with an identification module, an audio input/output (I/O) port, a video I/O port, and an earphone port. In response to the interface 160 being connected to an external device, the electronic device 100 may perform an appropriate control associated with the connected external device.

The memory 170 may store data supporting various functions of the electronic device 100. The memory 170 may store application programs (or applications) run in the electronic device 100, data for operation of the electronic device 100, and instructions. At least a portion of the application programs may be downloaded from an external server through wireless communication. Also, at least a portion of the application programs may exist in the electronic device 100 for a basic function (for example, call forwarding and outgoing function and message receiving and outgoing function) of the electronic device 100 from the time of manufacture. The application program may be stored in the memory 170, installed in the electronic device 100, and run by the controller 180 to perform an operation (or function) of the mobile terminal.

The controller 180 may generally control an overall operation of the electronic device 100 in addition to operations related to the application programs. The controller 180 may process a signal, data, information, and the like input or output through the aforementioned components or run the application program stored in the memory 170, thereby providing information to a user or performing appropriate information or function.

Also, to run the application program stored in the memory 170, the controller 180 may control at least a portion of the components shown in FIG. 1. Furthermore, to run the application program, the controller 180 may operate a combination of two or more components among the components included in the electronic device 100.

Further, the controller 180 may be referred to as a processor according to an example embodiment.

The power supply 190 may supply power to each component included in the electronic device 100 by receiving external or internal power under a control of the controller 180. The power supply 190 may include a battery. The battery may include a built-in battery or a removable battery.

Further, the power supply part 190 may include a charging port, and the charging port may be configured as an example of the interface part 160 to which an external charger that supplies power for charging the battery is electrically connected.

At least some of the respective components may operate in cooperation with each other in order to implement an operation, control, or a control method of an electronic device according to various example embodiments described below. Further, the operation, the control, or the control method of the electronic device may be implemented on the electronic device by driving at least one application program stored in the memory 170.

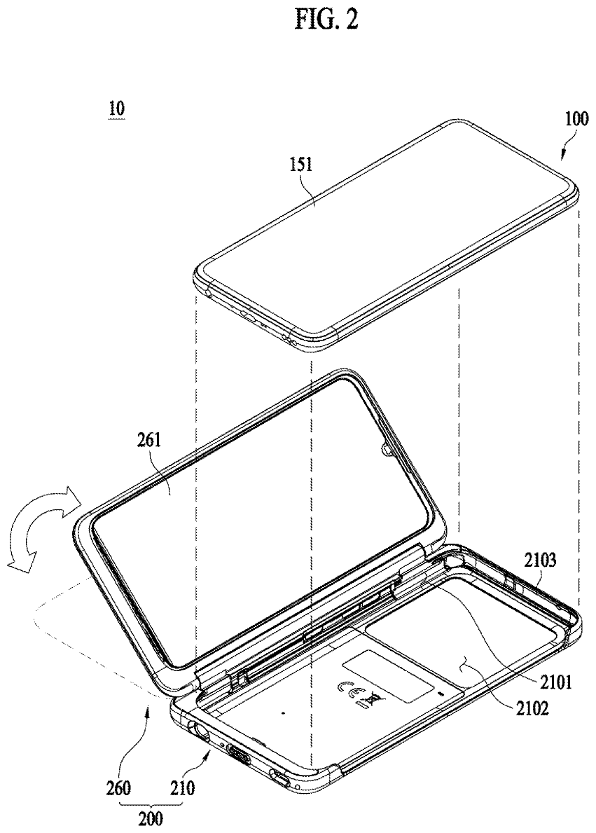

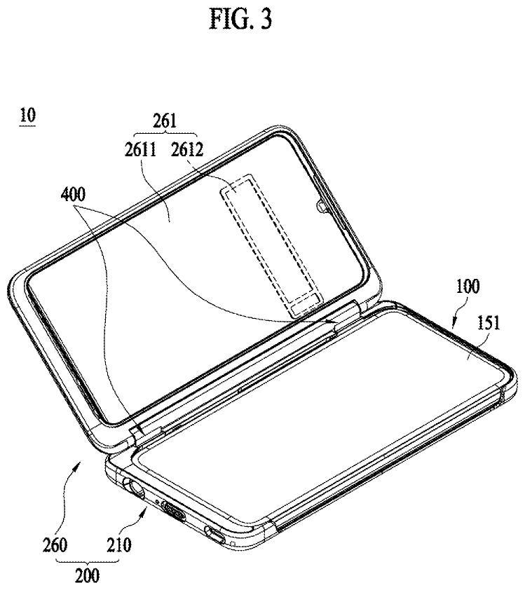

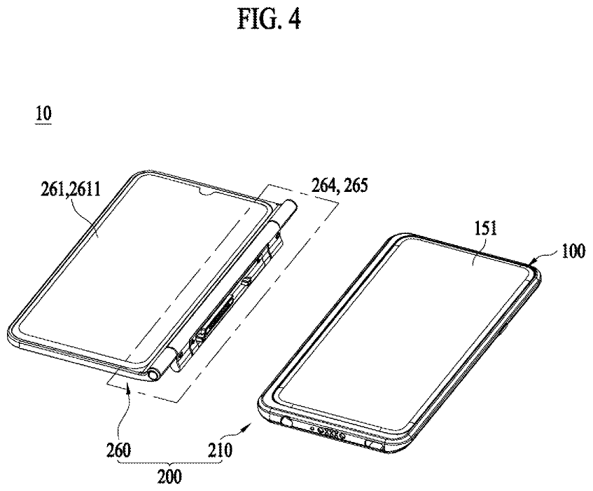

FIGS. 2 to 4 are conceptual diagrams for illustrating a terminal set 10 related to the present disclosure. FIG. 2 illustrates a state before the electronic device (or an electronic device) 100 is coupled to an auxiliary device 200 in the terminal set 10 related to the present disclosure. FIG. 3 illustrates a state in which the electronic device 100 is coupled to the auxiliary device 200. Further, FIG. 4 illustrates a state in which a covering member 260 of the auxiliary device 200 is separated in the state of FIG. 3. FIGS. 2 to 4 are also referred to for better understanding.

The terminal set 10 of the present disclosure includes the electronic device 100 having a display and the auxiliary device 200 providing an extended display in combination with the electronic device 100. The auxiliary device 200 again includes a receiving member 210 that is an area where the electronic device 100 is coupled, and a covering member 260 that selectively covers the electronic device 100 and mounts an extended display.

As described above, in the terminal set 10 of the present disclosure, the electronic device 100 and the auxiliary device 200 each form an output area to provide multiple displays, thereby increasing usability. A display provided in the electronic device 100 is referred to as a first display 151, and a display provided in the auxiliary device 200 is referred to as a second display 261.

The second display 261 may be provided on both the inner and outer surfaces of the covering member 260. The second display 261 provided on the inner surface is defined as an inner second display 2611, and the second display 261 provided on the outer surface is defined as an outer second display 2612. The inner second display 2611 may be used to be viewed simultaneously with the first display when the covering member 260 is unfolded, and the outer second display 2612 may be used to be viewed on the terminal set 10 when the covering member 260 is closed.

The first display 151 and the second display 261, in particular, the inner second display 2611 may be output in connection with each other. For example, the first display 151 and the inner second display 2611 may be mirrored and output, or a screen output on the first display 151 may be moved to the inner second display 2611 to be output. Alternatively, execution screens of one application or a plurality of related applications may be dividedly output on the first display and the inner second display 2611. For example, a controller of a game application may be output to the first display 151, and the game content may be output to the inner second display 2611. In other words, the terminal set 10 of the present disclosure may operate as one device having a plurality of displays, which indicates that the auxiliary device 200 shares various configurations provided on the electronic device 100.

The outer second display 2612 may output relatively simple information. For example, the outer second display 2612 may perform a function of outputting simple text information or image information such as call reception, message reception and alarm. Since the outer second display 2612 is provided, there is an advantage that information may be identified without a separate operation while the covering member 260 is closed.

The controller 180 and the power supply part 190 of the electronic device 100 may supply power to the second display 261 as well as the first display 151 and transmit/receive data. Therefore, the auxiliary device 200 may operate without the separate controller 180 and the power supply part 190. This reduces the weight or volume of the auxiliary device 200 and may also achieve the effect of reducing manufacturing cost.

The electronic device 100 is physically coupled to the auxiliary device 200 for power supply and data transmission/reception to the second display 261, and the auxiliary device 200 includes a circuit for electrically connecting the electronic device 100 and the second display 261. This is defined as a protection circuit part.

The auxiliary device 200 of the present disclosure proposes a form in which the covering member 260 is selectively attached to and detached from the receiving member 210. Advantages of the auxiliary device 200 having the detachable covering member 260 are as follows.

First, when the covering member 260 is not used, a function of physically protecting the electronic device 100 may be obtained by coupling only the receiving member 210 to the electronic device 100. In the conventional case in which the covering member 260 is always fixed to the receiving member 210, it must be used with a large volume and weight despite not using the covering member 260, and the grip feeling of the electronic device 100 gets poor. Therefore, the disadvantage may be compensated for by coupling only the receiving member 210 to the electronic device 100.

Second, the detachable covering member 260 may be continuously used even if the electronic device 100 and the receiving member 210 are replaced. For example, even if the used receiving member 210 coupled to the specific electronic device 100 is damaged or lost, only the receiving member 210 may be replaced and the existing covering member 260 may be used as it is.

Third, even when the electronic device 100 having a shape or a size different from those of the previously used electronic device 100 and the receiving member 210 are used, the previously used covering member 260 may be coupled and used. Of course, this assumes that the electronic device 100 having the different shape or size and the receiving member 210 are configured to be compatible with the existing covering member 260.

Fourth, the covering member 260 may be coupled in another form. For example, when the covering member 260 is turned over and configured to be coupled to the receiving member 210, the two displays 151 and 261 may be viewed in the same direction or in opposite directions. Thus, a variety of user experiences may be provided.

Referring to FIG. 4, in some cases, the receiving member 210 may be provided in the form of a terminal case. In such a case, the receiving member 210 forms a seating area on which the rear surface of the electronic device 100 may be seated. When the electronic device is seated, the receiving member 210 forms an output area, which is an area open so that the first display 151 may be viewed from the front, of the display part of the electronic device 100. At the same time, at least one area of the rear surface of the receiving member 210 also has an opening so that a camera of the electronic device 100 may be exposed. The side circumference of the receiving member 210 is formed to correspond to the shape of the side circumference of the electronic device 100 so that the electronic device 100 may be coupled to the terminal case 210 to fit.

The covering member 260 and the receiving member 210 of the auxiliary device 200 of the present disclosure are coupled and separated by a fastening part 264.

The covering member 260 forms at least one axis of rotation at one corner of the receiving member 210 when coupled to the receiving member 210 to selectively cover the seating area.

The covering member 260 may be detachably coupled to a side of one corner of the receiving member 210 or to a side and rear surface. Coupling to the side may minimize the increase in the thickness of the terminal set 10, and coupling to the side and rear surface may minimize the increase in the bezel of the terminal set 10. In the present disclosure, the coupling to the side of the receiving member 210 is described, but in some cases, coupling to a rear surface of the receiving member 210 may also be possible.

The covering member 260 provides the above-described second display 261 by mounting the display panel 2611. The display panel 2611 is exposed on one surface of the covering member 260 to form an output area. The display panel 2611 may include a touch panel for receiving an external touch input.

A hinge part 265 is provided on the covering member 260 to provide at least one axis of rotation so that the covering member 260 may rotate with respect to the receiving member 210. The covering member 260 rotated by the hinge part 265 selectively covers the seating area of the receiving member 210.

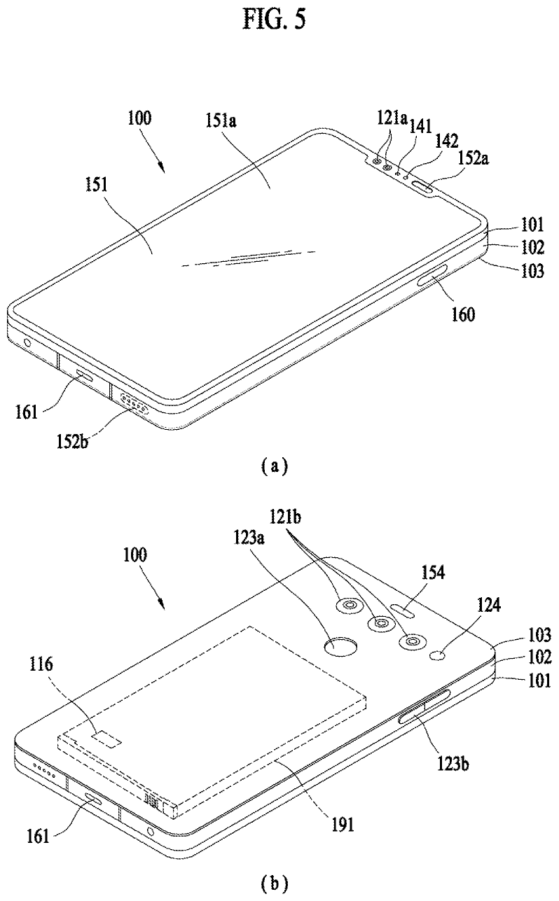

(a) of FIG. 5 and (b) of FIG. 5 are a front perspective view and a rear perspective view of the electronic device 100 related to the present disclosure.

Referring to (a) of FIG. 5, the disclosed electronic device 100 has a bar-shaped terminal body. However, the present disclosure is not limited thereto. The electronic device 100 may be applied to various structures such as a watch type, a clip type, a glass type, or a folder type in which two or more bodies are coupled to be relatively movable, a flip type, a slide type, a swing type, and a swivel type. The present disclosure is related to a specific type of the electronic device, but descriptions regarding a specific type of the electronic device may be generally applied to other types of electronic devices.

Here, the terminal body may be understood as a concept referring to the electronic device 100 as at least one aggregate.

The electronic device 100 includes a case (e.g., a frame, a housing, a cover, etc.) forming an exterior. As illustrated, the electronic device 100 may include a front case 101 and a rear case 102. Various electronic components are disposed in the inner space formed by the coupling of the front case 101 and the rear case 102. At least one middle case may be additionally disposed between the front case 101 and the rear case 102.

The display 151 may be disposed on the front surface of the terminal body to output information. As illustrated, a window 151a of the display 151 may be mounted on the front case 101 to form a front surface of the terminal body together with the front case 101.

In some cases, an electronic component may also be mounted on the rear case 102. Electronic components mountable to the rear case 102 include a removable battery, an identity module, a memory card and the like. In this case, a rear surface cover 103 for covering a mounted electronic component may be detachably coupled to the rear case 102. Therefore, when the rear surface cover 103 is separated from the rear case 102, the electronic component mounted on the rear case 102 is exposed to the outside.

As illustrated, when the rear surface cover 103 is coupled to the rear case 102, a portion of a side surface of the rear case 102 may be exposed. In some cases, when combined, the rear case 102 may be completely covered by the rear surface cover 103. Meanwhile, the rear surface cover 103 may be provided with an opening for exposing a camera 121b or an audio outputting part 152b to the outside.

The cases 101, 102 and 103 may be formed by injecting synthetic resin or may be formed of metal, for example, stainless steel (STS), aluminum (Al) and titanium (Ti).

Unlike the above example embodiment in which a plurality of cases provide an internal space for accommodating various electronic components, the electronic device 100 may be constituted such that one case provides an internal space. In this case, the single-body electronic device 100 in which synthetic resin or metal is connected from a side to the back may be implemented.

Further, the electronic device 100 may include a waterproof part (not illustrated) that prevents water from permeating into the terminal body. For example, the waterproof part may be provided between the window 151a and the front case 101, between the front case 101 and the rear case 102, or between the rear case 102 and the rear surface cover 103, and when these are coupled to, a waterproof member that seals the inner space may be included.

The electronic device 100 may include the display 151, first and second audio outputting parts 152a and 152b, the proximity sensor 141, the illumination sensor 142, the optical output part 154, first and second cameras 121a and 121b, first and second operation parts 123a and 123b, the microphone 122 and the interface part 160.

Hereinafter, the example embodiments illustrated in (a) and (b) of FIG. 5 of the electronic device 100 will be described, in which the display 151, the first audio outputting part 152a, the proximity sensor 141, the illumination sensor 142, the optical output part 154, the first camera 121a and the first operation part 123a are disposed on the front surface of the terminal body, the second operation part 123b, the microphone 122 and the interface part 160 are disposed on the sides of the terminal body, and the second audio outputting part 152b and the second camera 121b are disposed on the rear surface of the terminal body.

However, the components are not limited to the arrangement. The components may be excluded or replaced as necessary, or may be disposed on different sides. For example, the first operation part 123a may not be provided on the front surface of the terminal body, and the second audio outputting part 152b may be provided on a side surface of the terminal body rather than the rear surface of the terminal body.

The display 151 displays (outputs) information processed by the electronic device 100. For example, the display 151 may display execution screen information of an application program driven in the electronic device 100, or user interface (UI) and graphic user interface (GUI) information according to the execution screen information.

The display 151 may include at least one of a liquid crystal display (LCD), a thin film transistor-liquid crystal display (TFT LCD), an organic light-emitting diode (OLED), a flexible display, a 3D display and an e-ink display.

Further, two or more displays 151 may be present according to an implementation form of the electronic device 100. In this case, a plurality of displays may be spaced apart on one surface or disposed integrally in the electronic device 100, or the plurality of displays may be respectively disposed on different surfaces of the electronic device 100.

The display 151 may include a touch sensor for sensing a touch on the display 151 so as to receive a control command input by a touch method. Using the touch sensor, when a touch is made on the display 151, the touch sensor detects the touch, and the controller 180 may be configured to generate a control command corresponding to the touch based thereon. The content input by the touch method may be letters or numbers, or menu items that may be instructed or designed in various modes.

Further, the touch sensor may be constituted in the form of a film having a tough pattern and disposed between the window 151a and a display (not illustrated) on a rear surface of the window 151a, or may be a metal wire directly patterned on the rear surface of the window 151a. Alternatively, the touch sensor may be formed integrally with the display. For example, the touch sensor may be disposed on a substrate of the display or provided inside the display.

As such, the display 151 may form a touch screen together with the touch sensor, and in this case, the touch screen may function as the user input part 123 (see FIG. 1). In some cases, the touch screen may replace at least some functions of the first operation part 123a.

The first audio outputting part 152a may be implemented as a receiver that delivers a call sound to a user's ear. The second audio outputting part 152b may be implemented in the form of a loud speaker that outputs various alarm sounds or multimedia playback sounds.

Sound holes for emitting sound generated from the first audio outputting part 152a may be formed in the window 151a of the display 151. However, the present disclosure is not limited thereto. The sound may be emitted along the assembly gap (for example, the gap between the window 151a and the front case 101) between structures. In this case, the appearance of the electronic device 100 may be more simplified because the holes independently formed for sound output are not visible or hidden.

The optical output part 154 is configured to output a light for notifying the occurrence of an event. Examples of the event include message reception, call signal reception, missed call, alarm, schedule notification, email reception, and information reception through an application. When a user's identification for an event is detected, the controller 180 may control the optical output part 154 to end the light output.

The first camera 121a processes an image frame of a still image or a moving image acquired by an image sensor in a shooting mode or a video call mode. The processed image frame may be displayed on the display 151 and stored in the memory 170.

The first and second operation parts 123a and 123b are example embodiments of the user input part 123 manipulated to receive a command for controlling the operation of the electronic device 100, and may also be collectively referred to as a manipulating portion. The first and second operation parts 123a and 123b may be adopted in any manner as long as they are in a tactile manner in which a user operates while receiving a tactile feeling, such as a touch, a push and a scrolling. Further, the first and second operation parts 123a and 123b may be operated in a way that the user does not have a tactile feeling through a proximity touch, a hovering touch and the like.

In the drawing, the first operation part 123a is an example embodiment as a touch key, but the first operation part 123a is not limited thereto. For example, the first operation part 123a may be a push key (a mechanical key), or a combination of a touch key and a push key.

The contents input by the first and the second operation parts 123a and 123b may be variously set. For example, the first operation part 123a may receive commands for, such as menu, a home key, cancel, search and the like, and the second operation part 123b may receive a command for adjusting the volume of the sound output from the first audio outputting part 152a and the second audio outputting part 152b, and a command such as switching to the touch recognition mode of the display 151.

Further, as another example of the user input part 123, a rear surface input part (not illustrated) may be provided on the rear surface of the terminal body. The rear surface input part manipulated to receive a command for controlling an operation of the electronic device 100, and an input content may be set in various ways. For example, commands for such as power on/off, start, end and scrolling, a command for adjusting the volume of sound output from the first and second audio outputting parts 152a and 152b, and a command such as switching to the touch recognition mode of the display 151 may be input. The rear surface input part may be implemented in a form capable of input by a touch input, a push input or a combination thereof.

The rear surface input part may be disposed to overlap the front display 151 in the thickness direction of the terminal body. As an example embodiment, the rear surface input part may be disposed on the upper rear portion of the terminal body so that when a user holds the terminal body with one hand, the user may easily operate the terminal body using the index finger. However, the present disclosure is not limited thereto, and the position of the rear surface input part may be changed.

As such, when the rear surface input part is provided on the rear surface of the terminal body, a new type of user interface using the rear surface input part may be implemented. Further, when the first operation part 123a is not disposed on the front surface of the terminal body, by the touch screen or the rear surface input part described above replacing at least some functions of the first operation part 123a provided on the front of the terminal body, the display 151 may be constituted with a larger screen.

Further, the electronic device 100 may be provided with a fingerprint recognition sensor for recognizing a user's fingerprint, and the controller 180 may use fingerprint information detected through the fingerprint recognition sensor as an authentication means. The fingerprint recognition sensor may be embedded in the display 151 or the user input part 123.

The microphone 122 is configured to receive a user's voice and other sounds. The microphones 122 may be provided at a plurality of locations and configured to receive stereo sound.

The interface part 160 serves as a passage through which the electronic device 100 may be connected to an external device. For example, the interface part 160 may be at least one of a connection terminal for connection with another device (e.g., earphones, an external speaker), a port for short-distance communication [for example, an infrared port (the Infrared Data Association (IrDA) Port), a Bluetooth port, a wireless LAN port, etc.], or a power supply terminal for supplying power to the electronic device 100. The interface part 160 may be implemented in the form of a socket accommodating an external card, such as a subscriber identification module (SIM) or a user identity module (UIM), or a memory card for information storage.

The second camera 121b may be disposed on the rear surface of the terminal body. In this case, the second camera 121b has a photographing direction substantially opposite to that of the first camera 121a.

The second camera 121b may include a plurality of lenses arranged along at least one line. The plurality of lenses may be arranged in a matrix form. The camera may be referred to as an “array camera.” When the second camera 121b is configured as an array camera, images may be captured in various ways using a plurality of lenses. When the second camera 121b is configured as an array camera, images may be captured in various ways using a plurality of lenses, and better quality images may be acquired.

A flashbulb 124 may be disposed adjacent to the second camera 121b. The flashbulb 124 illuminates light toward a subject when the subject is photographed by the second camera 121b.

The second audio outputting part 152b may be additionally disposed on the terminal body. The second audio outputting part 152b may function as a stereo together with the first audio outputting part 152a, and may be used to implement a speakerphone mode during a call.

At least one antenna for wireless communication may be provided in the terminal body. The antenna may be built in the terminal body or formed in a case. For example, an antenna forming a part of the broadcast receiving module 111 (see FIG. 1) may be configured to be withdrawn from the terminal body. Alternatively, the antenna may be formed in a film type and attached to the inner surface of the rear surface cover 103, or a case including a conductive material may be configured to function as an antenna.

The terminal body is provided with a power supply part 190 (see FIG. 1) for supplying power to the electronic device 100. The power supply part 190 may include a battery 191 built into the terminal body or detachably constituted from the outside of the terminal body.

The battery 191 may be configured to receive power through a power cable connected to the interface part 160. Further, the battery 191 may be configured to be wirelessly charged through a wireless charging device. The wireless charging device may be implemented by a magnetic induction method or a resonance method (magnetic resonance method).

Meanwhile, the drawing illustrates that the rear surface cover 103 is coupled to the rear case 102 to cover the battery 191 to restrict the detachment of the battery 191 and to protect the battery 191 from external shocks and foreign substances. When the battery 191 is detachably constituted to the terminal body, the rear surface cover 103 may be detachably coupled to the rear case 102.

An accessory that protects the appearance of the electronic device 100, or assists or expands functions of the electronic device 100 may be added to the electronic device 100. An example of the accessory may be a cover or a pouch that covers or accommodates at least one surface of the electronic device 100. The cover or the pouch may be configured to extend a function of the electronic device 100 by being linked to the display 151. As another example of the accessory, there may be a touch pen for assisting or extending a touch input to a touch screen.

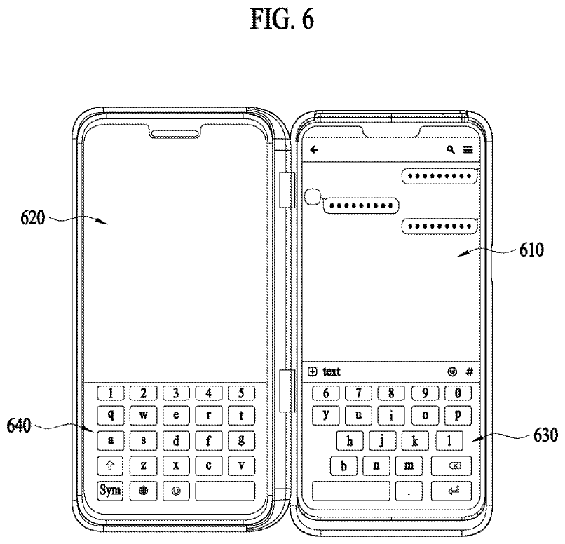

FIG. 6 is a conceptual diagram of an electronic device according to an embodiment of the present disclosure. Specifically, FIG. 6 illustrates an example in which a keyboard interface is provided in an electronic device including a plurality of displays.

Referring to FIG. 6, the electronic device may include a first body including a first display 610, and may be coupled to a second body including a second display 620. In this case, the electronic device may control each of the first display 610 and the second display 620 by linking them based on the coupling.

Based on the coupling, the first display 610 and the second display 620 may be connected, and the electronic device may output the keyboard interface to the first display 610 and the second display 620 based on the connection.

Specifically, as illustrated in FIG. 6, the electronic device may divide and output the keyboard interface onto the first display 610 and the second display 620. Specifically, one area 630 of the keyboard interface may be displayed on the first display 610, and another area 640 of the keyboard interface may be displayed on the second display 620.

Here, the keyboard interface may be a user interface (UI) corresponding to a keyboard. With respect to the keyboard interface, texts (or letters, or characters) may be designated for each area. Accordingly, when inputs are applied to the keyboard interface, the electronic device may generate a final text by sequentially combining texts corresponding to the inputs.

For example, when an input to an area corresponding to “⊏” and an input to an area corresponding to “├” are sequentially applied, the electronic device may generate the text “⊏├” based on the areas and time to which the inputs are applied.

For example, when an input to an area corresponding to “a” and an input to an area corresponding to “k” are sequentially applied, the electronic device may generate the text “ak” based on the areas and time to which the inputs are applied.

In an example embodiment, the outputs of one area 630 and another area 640 of the keyboard interface may be performed by one application or a plurality of applications, depending on an implementation method.

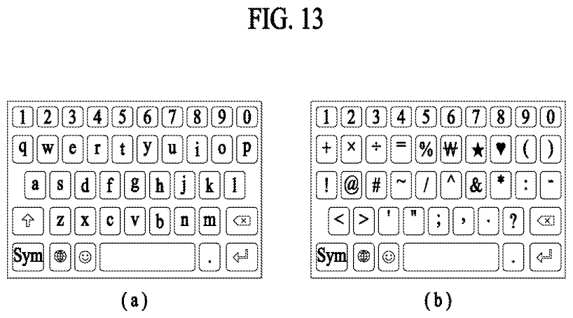

Meanwhile, in FIG. 6, the text provided by the keyboard interface exemplifies numbers and Korean characters, but the present disclosure is not limited thereto. The keyboard interface may also provide a variety of texts, such as English characters or special characters. An example embodiment of the text arrangement in the case may refer to FIG. 13.

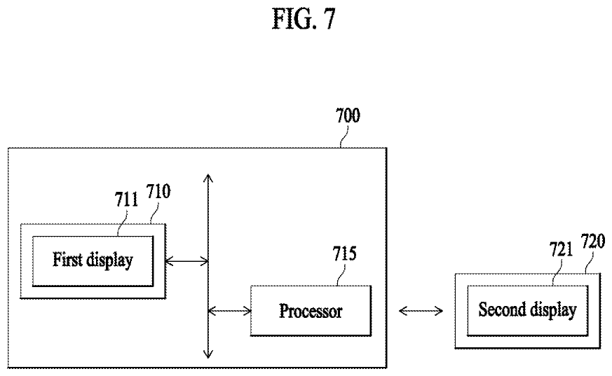

FIG. 7 is a functional block diagram of an electronic device according to an example embodiment of the present disclosure.

Referring to FIG. 7, an electronic device 700 may include a first body 710 having (or including) a first display 711 and a processor 715. At least some of the first body 710, the first display 711, the processor 715, a second body 720 and a second display 721 may be implemented by including at least one processor (or a microprocessor) according to an example embodiment. Further, the at least some of the above may be implemented as hardware or software, or a combination of hardware and software.

The electronic device 700 may be selectively coupled to the second body 720 including the second display 721. The electronic device 700 coupled to the second body 720 may correspond to the terminal set 10 of FIG. 2. The electronic device 700 may be coupled to the second body 720 to be linked to the second display 721. As will be described later, the control of the second display 721 based on such link may be performed by the processor 715.

The first body 710 may be a hardware configuration including the first display 711. In some cases, the first body 710 may be provided with an additional function related to the operation of the electronic device or the first display 711. For example, a button for activating the first display 711 may be included, but the present disclosure is not limited thereto.

According to an example embodiment, the first display 711 may be implemented as a separate component instead of being included in the first body 710, and this is also the case for the second display 721.

The first display 711 may output (or display) at least a part of the keyboard interface. For example, the first display 711 may output the entire keyboard interface. For another example, the first display 711 may output an area for predetermined texts located on the right side of the keyboard interface. In this case, the area for the remaining texts located on the left side of the keyboard interface may be output on the second display 721.

The second display 721 may output at least a part of the keyboard interface. For example, the second display 721 may output the entire keyboard interface. For another example, the second display 721 may output an area for predetermined texts located on the left side of the keyboard interface. In this case, the area for the remaining texts located on the left side of the keyboard interface may be output on the first display 711.

Further, the above-described outputs of the first display 711 and the second display 721 may be performed based on the control of the processor 715 to be described later, but the present disclosure is not limited thereto.

The processor 715 may identify whether the second body 720 is coupled. The processor 715 may identify on the coupling based on identifying whether the second body 720 (or the second display 721) is wired or wirelessly connected. For example, the processor 715 may identify on coupling based on whether a signal or response related to a coupling is received.

The processor 715 may output an area of the keyboard interface corresponding to a keyboard on the first display 711 based on the coupling of the second body 720, and output another area of the keyboard interface to the second display 721. Here, the one area and the another area may be at least parts of a predetermined keyboard interface. For example, the one area of the keyboard interface may be an area for predetermined texts located on the right side of the keyboard interface, and the another area may be an area for the remaining texts located on the left side of the keyboard interface. However, the present disclosure is not limited thereto.

In an example embodiment, when the coupling of the second body 720 is identified, the processor 715 may output (or display) an area of the keyboard interface corresponding to a keyboard on the first display 711, and may be output (or displayed) another area of the keyboard interface on the second display 721.

In an example embodiment, when the coupling of the second body 720 is identified and a first input related to the divided output of the keyboard interface is received, the processor 715 may output an area of the keyboard interface corresponding to a keyboard to the first display 711, and another area of the keyboard interface on the second display 721.

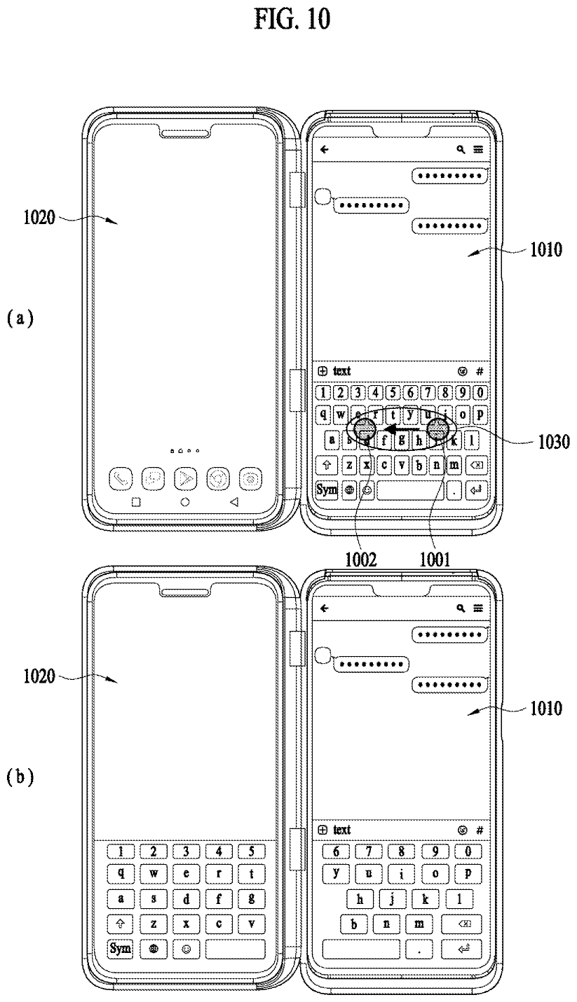

The first input related to the divided output of the keyboard interface may be an input for requesting that the keyboard interface to be displayed on the first display 711 and the second display 721. For example, the first input may include an input applied while the entire keyboard interface is displayed on the first display 711. A more specific example related thereto may refer to FIG. 10.

In an example embodiment, the processor 715 may output a first type of keyboard interface to the first display 711 and may output a second type of keyboard interface to the second display. For example, the first type may be a Korean keyboard, and the second type may be an English keyboard. In some cases, the processor 715 may output the first type of keyboard interface to the first display 711 and output the second type of keyboard interface to the second display when a specific input is applied.

When different types of keyboard interfaces are respectively output to the first display 711 and the second display 721, each keyboard interface may be a keyboard interface of a preset type suitable for a one-handed input.

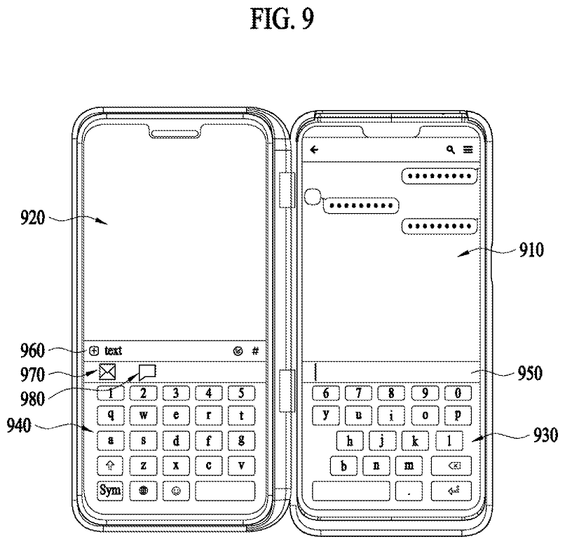

In an example embodiment, the processor 715 may display an icon for selecting a target application to be input through the keyboard interface on at least one of the first display 711 and the second display 721. When an input for an icon is received, the processor 715 may provide texts generated based on the keyboard interface to the target application. A more specific example related thereto may refer to FIG. 9.

In some cases, when an input for an icon is received, the processor 715 may identify the type of texts related to a target application. The processor 715 may output one area of the keyboard interface related to the identified type to the first display 711, and output another area of the keyboard interface to the second display 721.

Here, the type of text may include at least one of a text for a first language, a text for a second language and a text for a special character. For example, the type of text may include the English text, the Korean text and the special character text.

The processor 715 may generate a text based on an input to the keyboard interface and a time when the input is applied. For example, the processor 715 may identify an area to which an input is applied on the keyboard interface. In the keyboard interface, a text corresponding to each area may be previously designated, and based on this, the processor 715 may determine the text (e.g., A, B, e, 1, F) indicated by the input. The processor 715 may further identify the time when the input is applied. Accordingly, the processor 715 may combine texts indicated by inputs in the order of time in which the inputs are applied.

The processor 715 may identify whether the second input related to the keyboard interface is received. The second input may be an input requesting to output the keyboard interface divided and output to the first display 711 and the second display 721 through one display. The second input may be, for example, a drag input moving from left to right on the second display 721, but the second input is not limited thereto.

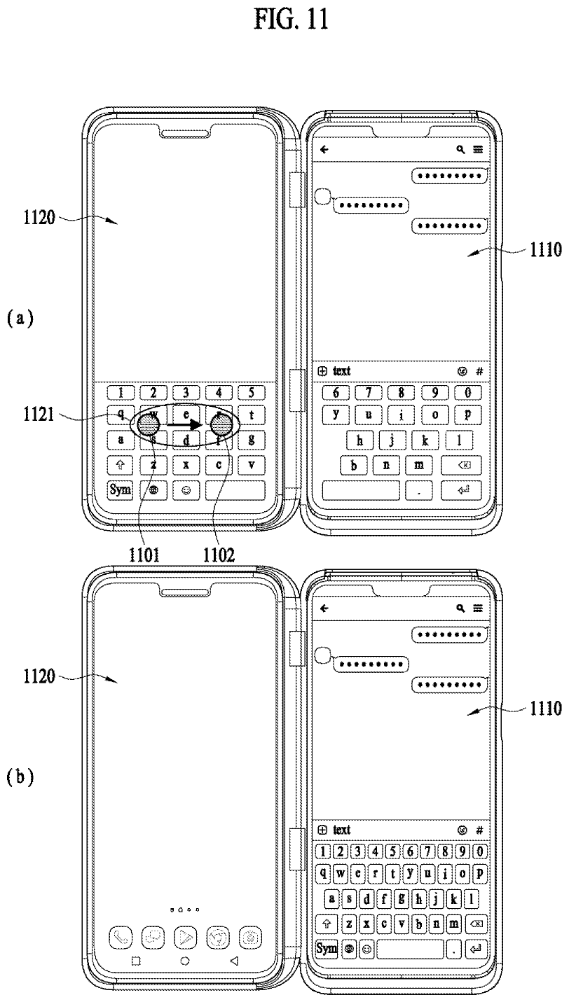

When the second input is received, the processor 715 may output a keyboard interface to one of the first display 711 and the second display 721. For example, based on reception of a second input, the processor 715 may output at least a portion of another area of the keyboard interface output to the second display 721 to the first display. A more specific example related thereto may refer to FIG. 11.

According to an example embodiment, an application displaying the keyboard interface on the first display 711 (hereinafter, the first keyboard application) and an application displaying the keyboard interface on the second display 721 (hereinafter, the second keyboard application) may be different from each other. In this case, the processor 715 may execute an application that displays a keyboard interface on the second display 721 based on the coupling to the second body or reception of the first input, so that the keyboard interface is displayed on the first display 711 and the second display 721.

For example, when the first keyboard application is coupled to the second body or the first input is received while the first keyboard application is running, the processor 715 may execute the second keyboard application. The processor 715 may change the type of the keyboard interface output through the first keyboard application to a designated type, in response to the execution of the second keyboard application. In this case, the designated type may be a type corresponding to one area of the above-described keyboard interface.

For another example, when coupled to the second body or when the first input is received, the processor 715 may execute the first keyboard application and the second keyboard application. The processor 715 may output an area of the keyboard interface to the first display 711 based on the first keyboard application. The processor 715 may output an area of the keyboard interface to the second display 721 based on the second keyboard application.

Although not illustrated, the electronic device 700 may include a sensor for measuring the posture of the electronic device 700. The sensor for measuring the posture may include, for example, at least one of a gyro sensor and a global positioning sensor (GPS). The electronic device 700 may acquire a sensor value indicating a posture (e.g., yaw, roll and pitch) through the above-described sensor. Since the sensor value is easy for those skilled in the art, a detailed description thereof will be omitted.

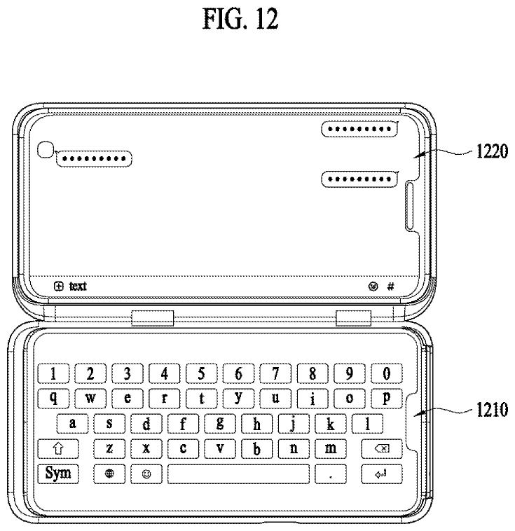

In this case, the electronic device 700 may identify whether the posture of the electronic device 700 is included in a predetermined posture range. When it is identified that an acquired sensor value is within a predetermined range, the electronic device 700 may output a keyboard interface to the first display 711 and may output content related to an application being executed on the second display 721. A more specific example related thereto may refer to FIG. 12.

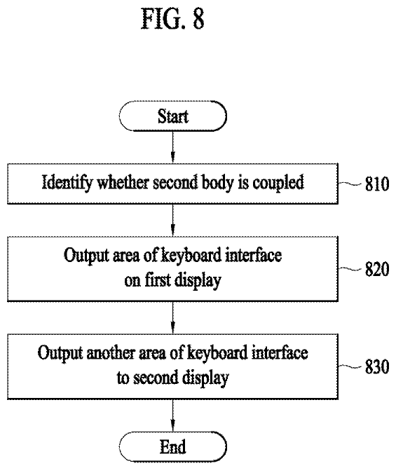

FIG. 8 is a flowchart illustrating a flow of each step of a method for controlling an electronic device according to an example embodiment of the present disclosure. Each step of the method illustrated in FIG. 8 may be performed in different orders from the order illustrated in the drawing in some cases. Further, in description with respect to FIG. 8, content overlapping with the previously described contents may be omitted.

Referring to FIG. 8, the processor of the electronic device (or an electronic device) may identify whether the second body is coupled in operation 810. Here, the second body includes the second display, and may be selectively coupled to the first body including the first display of the electronic device. Here, selectively coupling may indicate that detachment is freely possible, or indicate that the second body is coupled in a specific situation.

When it is identified that the second body is coupled, the processor may link to the second body or the second display. That is, based on the coupling to the second body, the processor may control not only the first display but also the second display.

The processor may output an area of the keyboard interface on the first display in operation 820. Specifically, the processor may output a designated area of the keyboard interface on the first display. For example, one area may be an area in which characters (or texts) designated to be input using the user's right hand on the keyboard are located.

The processor 715 may output another area of the keyboard interface to the second display in operation 830. Specifically, the processor may output another designated area of the keyboard interface on the second display. For example, the another area may be an area in which characters (or texts) designated to be input using the user's right hand on the keyboard are located.

According to an example embodiment, operation 820 and operation 830 may be performed irrespective of the order.

In an example embodiment, the processor may receive a predetermined input (e.g., a first input) in relation to an output of the keyboard interface using the first display and the second display. Upon receiving the predetermined input, the processor may output one area of the keyboard interface to the first display and another area of the keyboard interface to the second display.

In an example embodiment, in a state in which the keyboard interface is output using the first display and the second display, the processor may receive a predetermined input (e.g., a second input) for outputting the keyboard interface using one display. In this case, the processor may output the entire keyboard interface to one of the first display and the second display.

FIG. 9 is a diagram illustrating an example in which an electronic device outputs a keyboard interface and an application icon according to an example embodiment of the present disclosure.

Referring to FIG. 9, the electronic device may include a first display 910 and may be coupled to a second display 920. In an example embodiment, the second display 920 may be coupled to the left side of the first display 910 as illustrated. The electronic device may be linked with the second display 920 based on the coupling.

The keyboard interface may be displayed on the first display 910 and the second display 920. Specifically, one area 930 of the keyboard interface may be displayed on the first display 910, and another area 940 of the keyboard interface may be displayed on the second display 920.

The one area 930 may be a predetermined area of the left portion of the keyboard interface, and the another area 940 may be a predetermined area of the right portion of the keyboard interface. However, the present disclosure is not limited thereto, and the areas may be determined differently depending on the setting.

In an example embodiment, contents for different applications requiring a text input may be displayed on each of the first display 910 and the second display 920. For example, content related to a message application may be displayed on the first display 910, and content related to a memo application may be displayed on the second display 920.

An icon for an application executed on at least one of the first display 910 and the second display 920 may be displayed on at least one of the first display 910 and the second display 920.

For example, as illustrated, a first icon 970 related to the message application and a second icon 980 related to the memo application may be displayed on the second display 920. However, the present disclosure is not limited thereto. For example, the first icon 970 may be displayed on the first display 910 and the second icon 980 may be displayed on the second display 920.

A text input to an application may be performed using a keyboard interface. The user may allow a text to be input into the application by selecting an icon related to the application before or after inputting the text.

For example, when an input to the first icon 970 is applied, a cursor for a text input may be placed on a text input window 950 of the message application. Then, based on the input through the keyboard interface, a text may be generated in the input window 950 based on the cursor. If an input to the second icon 980 is applied, a cursor for a text input is placed on a text input window 960 of the memo application, and a text may be generated in the input window 960 based on this.

For another example, after a text is generated based on an input through the keyboard interface, an icon related to an application may be selected. In this case, the generated text may be provided to the application corresponding to the selected icon. That is, when the first icon 970 is selected, the generated text may be provided to the message application, and when the second icon 970 is selected, the generated text may be provided to the memo application.

According to an example embodiment, the electronic device may display content (or a screen) related to one application related to the selected icon between the first icon 970 and the second icon 980 through the first display 910 and the second display 920. Based on this, a keyboard interface may be applied to the target application, which is an application corresponding to the selected icon, so that a text input may be performed.

Further, FIG. 9 illustrates a case in which a Korean keyboard is provided in related to a keyboard interface. However, the present disclosure is not limited thereto, and keyboards for other languages or special characters may be provided.

In an example embodiment, the processor 715 may output a first type of keyboard interface to the first display 711 and may output a second type of keyboard interface to the second display. For example, the first type may be a Korean keyboard, and the second type may be an English keyboard. In some cases, the processor 715 may output the first type of keyboard interface to the first display 711 and output the second type of keyboard interface to the second display when a specific input is applied.

When different types of keyboard interfaces are respectively output to the first display 711 and the second display 721, each keyboard interface may be a keyboard interface of a preset type suitable for a one-handed input.

FIG. 10 illustrates an example of an input related to a keyboard interface in an electronic device according to an example embodiment of the present disclosure. Specifically, FIG. 10 illustrates a case in which an input for dividing and displaying a keyboard interface on a plurality of displays is applied.

Referring to (a) of FIG. 10, a keyboard interface may be output (or displayed) on a first display 1010, and the keyboard interface may not be output on a second display 1020. The keyboard interface output to the first display 1010 may correspond to the entire keyboard. In this case, the user may input a text by applying an input to the keyboard interface output on the first display 1010.

In this case, a first input 1030 related to the keyboard interface may be applied. The first input 1030 may be an input for requesting the keyboard interface to be output on the first display 1010 and the second display 1020. The first input 1030 may be, for example, a drag input for dragging from a first location 1001 to a second location 1002.

When the first input 1030 is applied, one area of the keyboard interface may be output to the first display 1010 and the other area may be output to the second display 1020 as illustrated in (b) of FIG. 10. For example, the one area may be an area preset to facilitate an input with the left hand on the keyboard interface, and the other area may be an area preset to facilitate an input with the right hand on the keyboard interface.

However, the present disclosure is not limited thereto, and the other area different from the one area may be designated as a specific area of the keyboard interface by a user's setting.

Further, the first input 1030 is not limited to the above-described example embodiment, and may be implemented in various forms such as, for example, a knock-on or a long touch. In some cases, the type of the first input 1030 may be changed according to a user's setting.

FIG. 11 is a diagram illustrating another example of an input related to a keyboard interface in an electronic device according to an example embodiment of the present disclosure. Specifically, FIG. 11 conceptually illustrates a case in which an input for displaying a divided keyboard interface on one display is applied.

Referring to (a) of FIG. 11, one area of a keyboard interface may be output (or displayed) on a first display 1110, and another area of the keyboard interface may be output (or displayed) on a second display 1120.

In this case, a second input 1121 related to the keyboard interface may be applied. The second input 1121 may be an input requesting to output the keyboard interface to one display. The second input 1121 may be, for example, a drag input for dragging from a first position 1101 to a second position 1102.

When the second input 1121 is applied, the keyboard interface may be output to the first display 1110 as illustrated in (b) of FIG. 11.

In an example embodiment, a display for outputting a keyboard interface according to a drag direction may be designated. For example, when the drag direction is from the first position 1101 to the second position 1102, the display for outputting the keyboard interface may be designated as the first display 1110. For another example, when the drag direction is from the second position 1102 to the first position 1101, the display for outputting the keyboard interface may be designated as the second display 1120.

FIG. 11 illustrates the case in which the entire keyboard interface is output to the first display 1110 based on the second input 1121. However, the present disclosure is not limited thereto. For example, a part of the keyboard interface may be output to the second display 1120. For example, the Korean keyboard of the keyboard interface may be output to the first display 1110 and the numeric keyboard may be output to the second display 1120.

FIG. 12 is a diagram illustrating an example of outputting a keyboard interface based on a posture of an electronic device according to an example embodiment of the present disclosure.

Referring to FIG. 12, a first display 1210 and a second display 1220 may be arranged vertically. The vertical arrangement may be performed, for example, based on a change in the posture of the electronic device in a state in which the first display 1210 and the second display 1220 are coupled as illustrated in FIG. 9. For another example, the vertical arrangement may be performed based on coupling of the second display to the upper end of the first display 1210 in a state where the first display 1210 is positioned in a landscape mode as illustrated.

Although not specifically illustrated, the electronic device may include a sensor (e.g., a gyro sensor) that measures a posture (e.g., yaw, roll and pitch), and based on this, the posture of the electronic device (or the first display 1210 or the second display 1220) may be measured. Since it is easy for those of ordinary skill in the art to measure a posture, a detailed description thereof will be omitted.

Based on the sensor's posture measurement, the electronic device may acquire a sensor value for a posture. The electronic device may identify whether the acquired sensor value falls within a predetermined range. If the sensor value is included in a first range, the electronic device may output the keyboard interface to a designated area of the first display 1210. In this case, content (or information) related to a running application may be output to the second display 1220.

FIG. 13 is a diagram illustrating an example of a text type of a keyboard interface of an electronic device according to an example embodiment of the present disclosure.

(a) of FIG. 13 illustrates an example of a keyboard interface providing an English keyboard, and (b) of FIG. 13 illustrates an example of keyboard interface that provides a special character keyboard.

Based on the connection of the second body (or the second display), the electronic device may output one area of the English keyboard or the special character keyboard to the first display and output the other one area to the second display.

Further, the range of languages provided by the keyboard interface is not limited to the above-described example embodiments, and various languages such as Chinese and Japanese may be provided.

An electronic device according to the example embodiments of the present disclosure and a method for controlling the same allow a user an easier input through a keyboard. The allowance is by the user holding the first display and the second display together, and by dividing and displaying the keyboard interface on the first display and the second display based on the coupling to the second body.

Combinations of each block in the block diagram attached to the specification and each step in the flowchart may be performed by computer program instructions. The computer program instructions may be embodied in the processor of a general purpose computer, special purpose computer or other programmable data processing equipment. Thus, the instructions, executed by the processor of a computer or other programmable data processing equipment, will create means for performing the functions described in each block of the block diagram or in each step of the flowchart. The computer program instructions may also be stored in a computer-usable or computer-readable memory that may direct a computer or other programmable data processing equipment to implement a function in a particular manner. Thus, it is also possible that the instructions stored in the computer usable or computer readable memory produce an article of manufacture containing instruction means for performing the function described in each block of the block diagram or in each step of the flowchart. The computer program instructions may be embodied on a computer or other programmable data processing equipment. Thus, it is also possible that a series of operational steps are performed on the computer or other programmable data processing equipment to create a computer-executed process, and instructions for executing the computer or other programmable data processing equipment provide steps for carrying out the function described in each block of the block diagram and in each step of the flowchart.

Additionally, each block may represent a module, a segment, or a portion of code that includes one or more executable instructions for executing a specified logical function(s). It should also be noted that in some alternative implementations the functions recited in the blocks may occur out of order. For example, two blocks shown one after another may be performed substantially at the same time, or the blocks may sometimes be performed in the reverse order according to a corresponding function.

The above descriptions are merely illustrative of the technical idea of the present disclosure, and various modifications and variations will be possible without departing from the essential quality of the present disclosure by those skilled in the art to which the present disclosure belongs. Therefore, the example embodiments disclosed in the present disclosure are intended to explain, not to limit the technical spirit of the present disclosure, and the scope of the technical spirit of the present disclosure is not limited by the example embodiments. The scope to be protected of the present disclosure should be interpreted by the following claims, and all technical ideas within the scope equivalent thereto should be interpreted as being included in the scope of the present disclosure.

What is claimed is:

1. An electronic device in which a first body having a first display and a second body having a second display are selectively coupled and linked, the electronic device comprising:
at least one processor which is provided at the first body so as to control the first display and which controls the first display and the second display on the basis of coupling to the second body,
wherein the at least one processor is configured to:
identify whether the second body is coupled; and
on the basis of the coupling to the second body, output one area of a keyboard interface corresponding to a keyboard on the first display and output another area of the keyboard interface on the second display.

2. The electronic device of claim 1, wherein the at least one processor is configured to:
display an icon for selecting a target application to be input through the keyboard interface on at least one of the first display and the second display; and
when an input for the icon is received, provide a text generated based on the keyboard interface to the target application.

3. The electronic device of claim 1, wherein the at least one processor is configured to:
display an icon for selecting a target application to be input through the keyboard interface on at least one of the first display and the second display;
when an input for the icon is received, identify a type of a text related to the target application; and
output an area of the keyboard interface related to the identified type to the first display, and output another area of the keyboard interface to the second display.

4. The electronic device of claim 3, wherein the type of the text includes at least one of a text of a first language, a text of a second language, and a text of a special character.

5. The electronic device of claim 1, wherein the at least one processor is configured to generate a text based on an input to the keyboard interface and a time when the input is applied.

6. The electronic device of claim 1, wherein the at least one processor is configured to:
identify whether a first input related to the keyboard interface is received; and
based on the reception of the first input and coupling to the second body, output an area of the keyboard interface to the first display and another area of the keyboard interface to the second display.

7. The electronic device of claim 6, wherein the first input includes an input applied while an entire keyboard interface is displayed through the first display.

8. The electronic device of claim 1, wherein the at least one processor is configured to:
identify whether a second input related to the keyboard interface is received; and
output at least a part of another area of the keyboard interface output to the second display based on the reception of the second input, to the first display.

9. The electronic device of claim 1, further comprising a sensor configured to measure a posture of the electronic device,
wherein the at least one processor is configured to:
acquire a sensor value for the posture of the electronic device through the sensor;
identify whether the acquired sensor value is within a predetermined range; and
when identified that the acquired sensor value is within the predetermined range, output the keyboard interface to the first display, and output content related to a running application to the second display.

10. A method of controlling an electronic device in which a first body having a first display and a second body having a second display are selectively coupled and linked, the method comprising:
identifying whether the second body is coupled; and
based on coupling to the second body, outputting an area of a keyboard interface corresponding to a keyboard on the first display and outputting another area of the keyboard interface on the second display.

11. The method of claim 10, further comprising:
displaying an icon for selecting a target application to be input through the keyboard interface on at least one of the first display and the second display; and
when an input for the icon is received, providing a text generated based on the keyboard interface to the target application.

12. The method of claim 11, further comprising:
displaying an icon for selecting a target application to be input through the keyboard interface on at least one of the first display and the second display; and
when an input for the icon is received, identifying a type of a text related to the target application,
wherein the outputting comprises:
outputting an area of a keyboard interface related to the identified type to the first display, and outputting another area of the keyboard interface to the second display.

13. The method of claim 12, wherein the type of the text includes at least one of a text of a first language, a text of a second language, and a text of a special character.

14. The method of claim 10, further comprising generating a text based on an input to the keyboard interface and a time when the input is applied.

15. The method of claim 10, further comprising identifying whether a first input related to the keyboard interface is received,
wherein the outputting comprises, based on the reception of the first input and coupling to the second body, outputting an area of the keyboard interface to the first display, and outputting another area of the keyboard interface to the second display.

16. The method of claim 15, wherein the first input comprises an input applied while an entire keyboard interface is displayed through the first display.

17. The method of claim 10, further comprising identifying whether a second input related to the keyboard interface is received,
wherein the outputting comprises outputting at least a part of another area of the keyboard interface output to the second display based on the reception of the second input, to the first display.

18. The method of claim 1, comprising:
acquiring a sensor value for a posture of the electronic device through a sensor measuring the posture; and
identifying whether the acquired sensor value is within a predetermined range,
wherein the outputting comprises:
when identified that the acquired sensor value is within the predetermined range, outputting the keyboard interface to the first display and outputting content related to an application being executed on the second display.

19. A computer-readable recording medium configured to store instructions for executing:
identifying whether a second body is coupled for an electronic device in which a first body including a first display and the second body including a second display are selectively coupled; and
based on coupling to the second body, outputting an area of a keyboard interface corresponding to a keyboard to the first display and outputting another area of the keyboard interface to the second display.
